(19) United States
(12) Patent Application Publication
(10) Pub. No.: US 2004/0238822 A1
(43) Pub. Date: Dec. 2, 2004

(54) Low leakage thin film transistor circuit

(76) Inventors: Chao-Yu Meng, Taichung (TW); An Shih, Changhua (TW)

Correspondence Address: Michael D. Bednarek, Shaw Pittman LLP, 1650 Tysons Boulevard, McLean, VA, 22102, US

(21) Appl. No.: 10/845,268

(22) Filed: May 14, 2004

(30) Foreign Application Priority Data
Jun. 2, 2003 (TW) 092114900

(51) Int. Cl. H01L 29/04

(52) U.S. Cl. 257/72

(57) ABSTRACT

The present invention provides a thin film transistor circuit having high aperture ratio. The circuit includes a first thin film transistor, a data line, and an adjusting capacitor. The first thin film transistor includes a semiconductor layer and a gate electrode. The semiconductor layer includes a drain region and a source region. The data line is connected to the source region of the first thin film transistor. The adjusting capacitor includes a first electrode plate connected to the drain region of the first thin film transistor. And the adjusting capacitor is covered by the data line.

### FIELD OF INVENTION

The present invention relates to a thin film transistor circuit, particularly to a thin film transistor circuit having high aperture ratio layout.

### BACKGROUND OF THE INVENTION

For active matrix displays, thin film transistors are employed as pixel switches to control images. As the display gray level increases, leakage current of the thin film transistor circuit has to be lower. U.S. Pat. No. 5,517,150 discloses a switch circuit comprising additional thin film transistor to lower the leakage current. As shown in FIG. 1, a first thin film transistor 101A and a second thin film transistor 101B are electrically connected in series, and an adjusting capacitor 106 for voltage adjustment is connected at its one end to a common connection point between the first and the second thin film transistor 101A and 101B. The other end of the adjusting capacitor 106 is connected to a reference voltage terminal 107. A storage capacitor 102 for voltage load is connected between the drain of the second thin film transistor 101B and a reference voltage terminal 105. When the switch circuit is used in a liquid crystal display, the reference voltage terminals 105 and 107 are so called counter electrode.

FIG. 2 illustrates a layout pattern diagram of the circuit in accordance with FIG. 1, in which both the adjusting capacitor 106 and the storage capacitor 102 are located inside the pixel. The adjusting capacitor 106 occupies a portion of the pixel, so that the aperture ratio decreases. A decreased aperture ratio leads to lower brightness of the display.

Therefore, the leakage current issue is solved but the low aperture ratio problem comes out.

### SUMMARY OF THE INVENTION

In one aspect of the present invention, a novel layout of thin film transistor circuit providing high aperture ratio is disclosed.

The present invention comprises a first thin film transistor, a data line, and an adjusting capacitor. The first thin film transistor includes a semiconductor layer and a gate electrode. The semiconductor layer includes a drain region and a source region of the first thin film transistor. The data line is connected to the source region of the first thin film transistor. The adjusting capacitor includes a first electrode connected to the drain region of the first thin film transistor. The adjusting capacitor is covered with the data line. Since the adjusting capacitor hides beneath the data line, the adjusting capacitor may occupy less area of the pixel.

The first electrode plate of the adjusting capacitor may be formed by extending the semiconductor layer of the first thin film transistor. The semiconductor layer may be of any semiconductor employed in the formation of transistors, preferably be polysilicon. This thin film transistor circuit further includes a common electrode. The second electrode plate of the adjusting capacitor is connected to the common electrode.

This thin film transistor circuit further includes a scan line, a second thin film transistor and a storage capacitor. Both the gate electrode of the first thin film transistor and the gate electrode of the second thin film transistor are connected to the scan line. The drain region of the first thin film transistor is connected to the source region of the second thin film transistor. The storage capacitor includes a first electrode plate connected to the drain region of the second thin film transistor. The storage capacitor further includes a second electrode plate connected to the above-mentioned common electrode. The gate electrode of the first thin film transistor may be connected to the gate electrode of the second thin film transistor to form an L-type dual gate electrode.

### BRIEF DESCRIPTION OF THE DRAWINGS

For a more complete understanding of the present invention, reference is now made to the following descriptions taken in conjunction with the accompanying drawings. Similar notation number across all figures represents similar element.

FIG. 1 is a circuit diagram according to prior art;

FIG. 2 is a layout pattern diagram of the circuit in accordance with FIG. 1;

FIG. 3A is a layout pattern diagram of the present invention;

FIG. 3B is a cross-sectional view along the line B-B in FIG. 3A; and

FIG. 3C is a cross-sectional view along the line C-C in FIG. 3A.

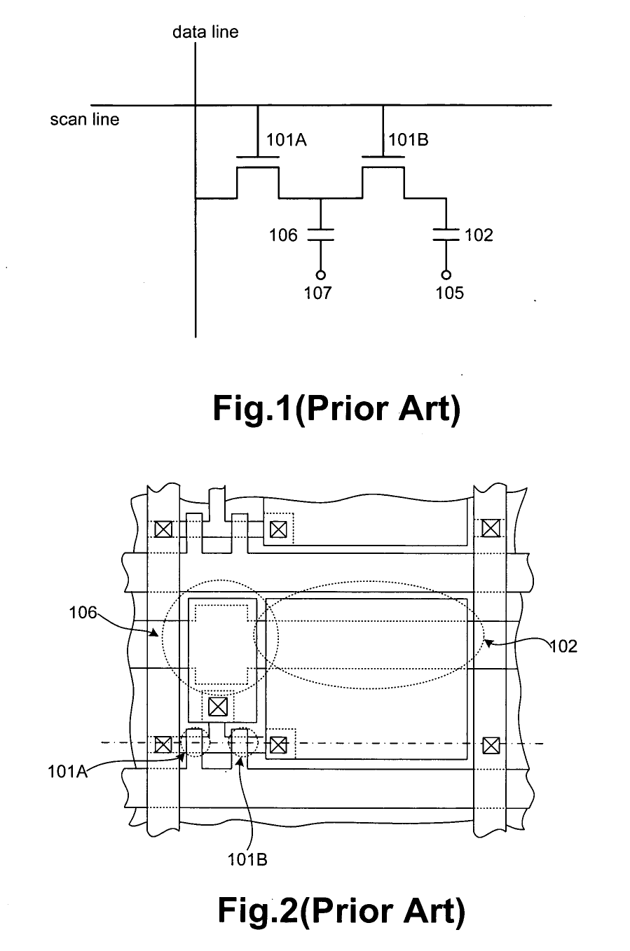

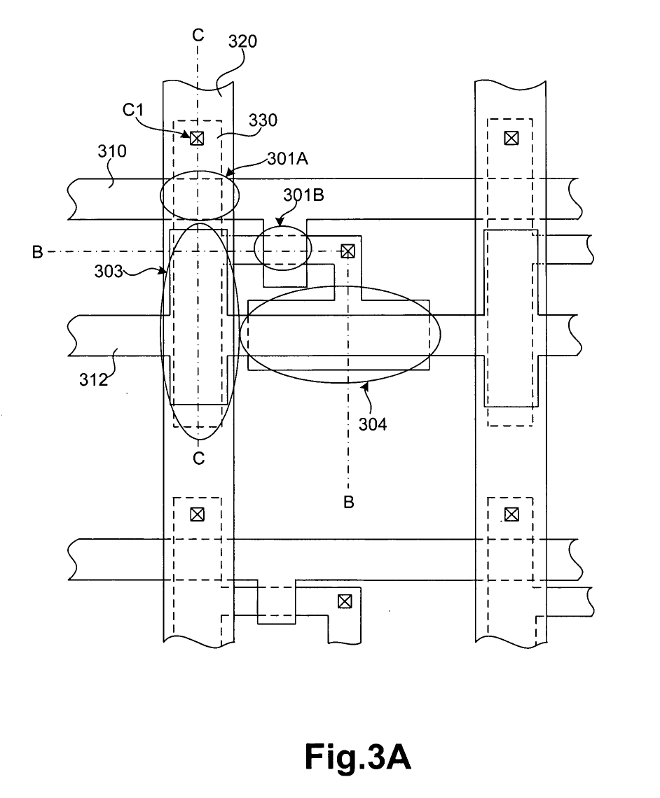

### DETAILED DESCRIPTION

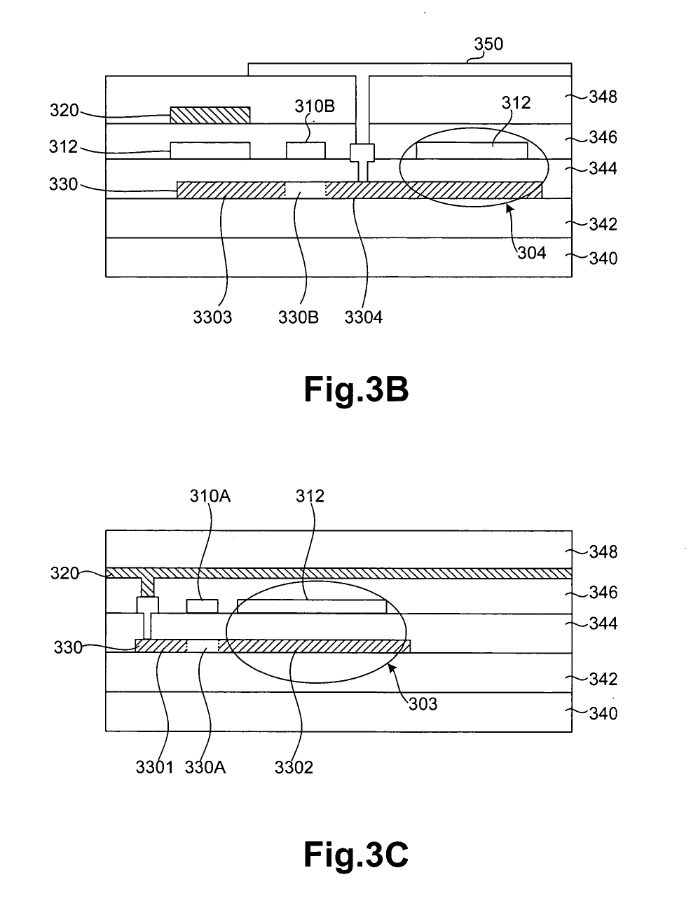

Referring to FIG. 3A, a novel layout pattern diagram having high aperture ratio is provided. FIGS. 3B and 3C are cross-sectional views along the line B-B and the line C-C in FIG. 3A, respectively.

A buffer layer 342 is formed on a substrate 340 and then a semiconductor layer 330 is formed thereon, which is covered with a gate insulator layer 344. A gate electrode (scan line) 310 and a common electrode 312 are formed on the gate insulator layer 344 and then are covered with an interlayer insulating film 346. A signal electrode (data line) 320 is formed on the interlayer insulating film 346. A pixel electrode 350 is deposited on an organic resin insulating film 348 formed over the signal electrode 320. Portions of the semiconductor layer 330 under the gate electrode 310 constitute intrinsic regions 330A and 330B, and the other portions of the semiconductor layer 330 are doped with phosphorous or arsenic at a high concentration so as to form source-drain regions 3301, 3302, 3303 and 3304.

This circuit includes a first thin film transistor 301A, a data line 320 formed of signal electrode, and an adjusting capacitor 303. The adjusting capacitor 303 is included to reduce the leakage current. The first thin film transistor 301A comprises the semiconductor layer 330 and the gate electrode 310A, wherein the semiconductor layer 330 further comprises the source region 3301, the intrinsic region 330A, and the drain region 3302. The data line 320 is connected to the source region 3301 of the first thin film transistor 301A through a contact hole C1. The first electrode plate of the adjusting capacitor 303 is part of the drain region 3302 of the first thin film transistor 301A, and the second electrode plate of the adjusting capacitor 303 is part of the common electrode 312. The first thin film transistor 301A and the adjusting capacitor 303 are covered with the data line 320. The overlapping area between the data line 320 and the adjusting capacitor 303 can be in the range of 10˜100% area of the adjusting capacitor 303.

The circuit further includes a scan line 310 formed of gate electrode, a second thin film transistor 301B and a storage capacitor 304. The second thin film transistor 301B comprises the semiconductor layer 330 and the gate electrode 310B, wherein the semiconductor layer 330 further comprises the source region 3303, the intrinsic region 330B, and the drain region 3304. Both the gate electrode 310A of the first thin film transistor 301A and the gate electrode 310B of the second thin film transistor 301B are connected to the scan line 310. The source region 3303 of the second thin film transistor 301B is connected to the drain region 3302 of the first thin film transistor 301A. The first electrode plate of the storage capacitor 304 is part of the semiconductor layer 330 connected to the drain region 3304 of the second thin film transistor 301B, and the second electrode plate of the storage capacitor 304 is part of the common electrode 312.

The spirit of the present invention is stated below referring to FIG. 3A. The adjusting capacitor 303 is covered with the data line 320. Since hiding beneath the data line 320, the adjusting capacitor 303 occupies less area of the pixel. Therefore, the aperture ratio is raised and the leakage current is still reduced.

In this embodiment, the gate electrode 310A of the first thin film transistor 301A is connected to the gate electrode 310B of the second thin film transistor 301B to form an L-type dual gate electrode, as shown in FIG. 3A.

The first electrode plate of the adjusting capacitor 303 is formed by extending the semiconductor layer 330. Here the semiconductor layer 330 can be a polysilicon layer. The first electrode plates of the adjusting capacitor 303 and the storage capacitor 304 are connected to each other and are formed in the same level, the same step in the process. Also the second electrode plates of the adjusting capacitor 303 and the storage capacitor 304 are connected to each other in a manner of the common electrode 312.

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A circuit, comprising:
a first thin film transistor, said first thin film transistor including a first semiconductor layer and a first gate electrode, said first semiconductor layer including a first source region and a first drain region;
a second thin film transistor, said second thin film transistor including a second semiconductor layer and a second gate electrode, said second semiconductor layer including a second source region and a second drain region, said second source region of said second thin film transistor being connected to said first drain region of said first thin film transistor;
a data line connected to said first source region of said first thin film transistor;
a storage capacitor, said storage capacitor including a first electrode plate comprising a portion of said second semiconductor layer of said second thin film transistor, said storage capacitor further including a second electrode plate; and
an adjusting capacitor, said adjusting capacitor including a first electrode plate comprising a portion of said first semiconductor layer of said first thin film transistor, said adjusting capacitor further including a second electrode plate,

2. wherein at least a portion of said adjusting capacitor is covered by said data line, forming an overlapping area. The circuit of claim 1, wherein said overlapping area is in the range of 10˜100% area of said adjusting capacitor.

3. The circuit of claim 1, wherein said first thin film transistor is covered with said data line.

4. The circuit of claim 1, wherein said first electrode plate of said adjusting capacitor and said first electrode plate of said storage capacitor are connected to each other and formed in the same level.

5. The circuit of claim 4, wherein said first electrode plate of said adjusting capacitor and said storage capacitor is a polysilicon layer.

6. The circuit of claim 1, wherein said first semiconductor layer of said first thin film transistor and said second thin film transistor is a polysilicon layer.

7. The circuit of claim 1, further comprising a common electrode, wherein said second electrode plate of said adjusting capacitor and said second electrode plate of said storage capacitor are connected to said common electrode.

8. The circuit of claim 1, further comprising a scan line, wherein said gate electrode of said first thin film transistor and said gate electrode of said second thin film transistor are connected to said scan line.

9. The circuit of claim 1, wherein said gate electrode of said first thin film transistor is connected to said gate electrode of said second thin film transistor to form an L-type dual gate electrode.
